(19) United States
(12) Patent Application Publication
(10) Pub. No.: US 2010/0117118 A1
(43) Pub. Date: May 13, 2010

(54) High electron mobility heterojunction device

(76) Inventors: Amir M. Dabiran, Chanhassen, MN (US); Andrew M. Wowchak, Hopkins, MN (US)

Correspondence Address: KINNEY & LANGE, P.A., THE KINNEY & LANGE BUILDING, 312 SOUTH THIRD STREET, MINNEAPOLIS, MN, 55415-1002, US

(21) Appl. No.: 12/462,737

(22) Filed: Aug. 7, 2009

Related U.S. Application Data
(60) Provisional application No. 61/086,884, filed on Aug. 7, 2008.

(51) Int. Cl. H01L 29/205; H01L 21/20

(52) U.S. Cl. 257/190; 438/478; 257/E21.09; 257/E29.091

(57) ABSTRACT

A method for providing a periodic table group III nitrides materials based heterojunction device comprising growing all layers therein by molecular beam epitaxy to result having a crystal defects concentration sufficiently small to allow electron mobilities in the sheet charge region to exceed 1100 cm2/volt-second. The invention includes the heterojunction device provided by this method.

### CROSS-REFERENCE TO RELATED APPLICATION(S)

This application claims the benefit of Provisional Patent Application No. 61/086,884 filed Aug. 7, 2008 for INTEGRATED PRODUCTION OF LOW DEFECT III-NITRIDE EPITAXIAL LAYERS FOR AlN/GaN HEMTS.

### STATEMENT OF GOVERNMENT INTEREST

This invention was supported by the Department of Defense under contract nos. W911QX-06-C-0083 and W911NF-06-C-0190. The Government has certain rights in the invention.

### BACKGROUND

This invention relates to high-performance high electron mobility transistors (HEMTs) and, more particularly, to such transistors based on Aluminum-Nitride/Gallium-Nitride (AlN/GaN) heterostructures and methods of making the same.

High Electron Mobility Transistors (HEMTs) based on AlGaN/GaN heterostructures, fabricated by different growth techniques such as molecular beam epitaxy (MBE) or metal organic chemical vapor deposition (MOCVD), are well known in the semiconductor field. These devices have demonstrated large power densities because of a unique combination of material properties including a high breakdown field, wide bandgap, large conduction band offset, and high saturated electron drift velocity. U.S. Pat. No. 5,192,987 to Khan et al. discloses AlGaN/GaN-based HEMTs grown on a buffer and a substrate, and a method for producing them. Other HEMTs have been described by Gaska et al., “High-Temperature Performance of AlGaN/GaN HFET's on SiC Substrates,” IEEE Electron Device Letters, Vol. 18, No 10, October 1997, Page 492; and Wu et al. “High Al-content AlGaN/GaN HEMTs With Very High Performance”, IEDM-1999 Digest pp. 925 927, Washington D.C., December 1999.

FIG. 1 illustrates in a schematic layer diagram a typical prior art AlGaN/GaN HEMT structure, 110, grown on a non-native material substrate, 111, such as c-plane sapphire (Al₂O₃), SiC, or Si(111). Depending on the material of substrate 111 and the choice of epitaxial growth technique (e.g., MBE or MOCVD) used to grow the periodic table group III nitride materials, a thin nucleation layer, 112, such as AlN, AlGaN or GaN is grown before growing a thicker semi-insulating GaN buffer layer, 115, followed by the growth of a GaN channel layer, 116. An AlGaN barrier layer, 118, is then grown on the GaN channel layer 116 to form an AlGaN/GaN heterostructure. It is well known that due to strong polarization fields in the strained AlGaN/GaN structure, a large density of electrons are accumulated at the interface to form an approximate two dimensional electron gas (2 DEG) sheet charge region, 117. Ohmic contacts to the 2 DEG region 117 are usually made through the surface of the AlGaN layer 118 in forming a source electrode, 121, and a drain electrode, 122, thereon. In a typical AlGaN/GaN HEMT, an electrically insulative gate isolation layer, 120, is provided on barrier layer 118 on which a gate electrode, 123, is formed. Alternatively, again typical in a AlGaN/GaN HEMT, a gate electrode, 123, instead forms a non-ohmic Schottky metal gate contact to the surface of the AlGaN layer 118. The conductivity of the 2 DEG region, which is proportional to the product of the sheet charge density and electron mobility, is modulated by applying a positive or negative bias voltage to the gate electrode 123 to increase or decrease the charge density in region 117, respectively.

For proper operation of an AlGaN/GaN HEMT 110, a highly resistive GaN buffer layer 115 is crucial to fully turn the device off (negligible source-drain current at a finite source-drain voltage) using a reasonable negative gate bias voltage However, undoped GaN layers have a small background n-type doping of <1E17 cm⁻³. To improve the resistivity of the GaN buffer 115, compensation doping using acceptor impurities, such as Mg, or doping by transition metals, such as Fe or Ni to form deep acceptor electron traps, is often used during growth to obtain semi-insulating GaN.

AlGaN/GaN HEMTs that are grown under optimized conditions can show very high power for DC operation. However, these devices often show much lower total microwave or radio-frequency (RF) power, manifested by a significant frequency slump or collapse in drain current as the operation frequency is increased. This effect severely reduces the output power and power-added efficiency of these devices. The cause appears to be the presence of carrier traps inside the AlGaN layer 116 and/or surface states on the AlGaN layer 116, between the gate 120 and drain 122 contacts, which deplete the channel in this region with time constants long enough to disrupt modulation of the channel charge during high frequency operation.

It is believed that the trap density of an AlGaN/GaN based HEMT is dependent upon the surface and volume of the AlGaN barrier layer. Reducing the thickness of the AlGaN layer is expected to reduce the total trapping volume, thereby reducing the trapping effect during high frequency operation. However, reducing the thickness of the AlGaN layer can have the undesirable effect of increasing the gate leakage. During normal operation, a bias is applied across the source and drain contacts and current flows between the contacts, primarily through the 2 DEG. However, in HEMTs having thinner AlGaN layers, current can instead leak into the gate creating an undesirable current flow from the source to the gate. Also, at a fixed Al composition, the thinner AlGaN means lower 2 DEG density resulting in a lower maximum drive current. Surface passivation with variety of insulating thin films, including silicon-nitride and aluminum-oxide, has been used to reduce the RF current collapse, but this has often produced other undesirable effects such as increased gate leakage and lower long term stability.

As the device dimensions are reduced for higher frequency operation, and the gate length start to approach closer to the thickness of the AlGaN barrier layer, the HEMT performance can also suffer from the so called “short channel effects”, G. Jessen et al., IEEE Trans. Elect. Dev., vol. 54, p. 2589 (2007). To mitigate this problem, the AlGaN layer is recessed under the gate area by carefully etching some portion of it. However, this introduces complexities in wafer processing steps, can result in introduction of other defects, and reduces the device yield. Finally, the operation of AlGaN/GaN HEMTs can suffer from alloy scattering resulting from naturally occurring small-scale inhomogeneities in composition of the AlGaN barrier layer 116 that can lower the channel conductivity by reducing the 2 DEG mobility.

To avoid many of the above problems, AlN/GaN HEMT structures, which replace the AlGaN barrier layer 116 with a thin (a few nanometers) AlN barrier layer, has been investigated previously. In spite of the great potential of AlN/GaN structure for high-frequency and high-power operation, much of the previous work using MOCVD or MBE growth techniques resulted in devices with very low 2 DEG mobility. The main problems with using MOCVD for growth of AlN/GaN HEMTs include higher growth temperatures, which result in cracking of the AlN layer due to mismatches in thermal coefficients of expansion, and difficulty in growing very abrupt AlN/GaN interfaces. Previous work using MBE growth of AlN/GaN HEMTs reduced problems facing MOCVD growth but failed to show high mobility structures due to a high density (>1E10 cm⁻²) of threading dislocations (TDs) in typical GaN buffers grown on sapphire or SiC. In other related work, a very thin AlN spacer (on the order of 1 atomic layer) was inserted between the AlGaN barrier layer and GaN channel and showed some improvement in 2 DEG sheet conductivity due to a reduction in electron scattering.

More recently, high-quality AlN/GaN HEMTs have been demonstrated using MBE growth on thick MOCVD grown GaN templates with a low density (<1E9 cm⁻³) of threading dislocations. However, a hybrid MOCVD-MBE growth of AlN/GaN HEMTs on thick GaN templates presents several important problems including large wafer bowing, which could prevent scaling to larger diameter substrates, and increased possibility of thin film cracking due to mismatches in lattice parameter and/or thermal coefficients of expansion. Furthermore, thin film growth on a GaN template that has been exposed to air can introduce unintentional impurities into the active device layer and/or lower the buffer resistivity. This latter problem may be eliminated with a vacuum connected MOCVD-MBE growth system, though the operation of a hybrid growth system may not be economical for commercial production of III-nitride devices. However, the problems resulting from thicker buffers, including wafer bowing and thin film cracking, are difficult to solve without thinner high-quality GaN buffers layers.

There is accordingly a compelling need in the art for provision of AlN/GaN HEMTs on low-defect GaN-based buffer layers grown on non-native substrates by MBE. Furthermore, the provision of low-defect GaN buffer layers can be applied to many other periodic table group III nitride materials based devices such as heterojunction bipolar transistors (HBTs) and photodiodes that can benefit from growth on lower defect buffer layers.

### SUMMARY

The present invention provides a method for providing a periodic table group III nitrides materials based heterojunction device comprising growing, on a substrate, a buffer structure having a plurality of buffer structure layers, including plural layers of different kinds of semiconductor materials, all grown by molecular beam epitaxy with an outer layer being of GaN. A channel layer of GaN is then grown on the outer layer by molecular beam epitaxy, and a barrier layer of AlN is thereafter grown on the channel layer by molecular beam epitaxy to form a heterojunction resulting in an electron sheet charge region being formed adjacent thereto, the buffer structure having a crystal defects concentration sufficiently small to allow electron mobilities in the sheet charge region to exceed 1100 cm2/volt-second. The invention includes the heterojunction device provided by this method.

### BRIEF DESCRIPTION OF THE DRAWINGS

FIG. 1 is a schematic layer diagram of the structure of an AlGaN/GaN HEMT known in the prior art;

FIG. 2 is a schematic structure of an embodiment of a periodic table group III nitrides materials based device of the present invention;

FIG. 3 shows atomic force microscopy images (AFM) of an AlN/GaN surface with two different thicknesses;

FIG. 4 shows transmission electron microscopy (TEM) images of an AlN/GaN HEMT structure;

FIG. 5 shows secondary ion mass spectroscopy (SIMS) depth profiling of Fe-doped GaN buffer layers; and

FIG. 6 shows characteristic DC and Pulsed source-drain current versus voltage (I-V) curves as selected by various gate voltages for a MOS-HEMT example of the present invention.

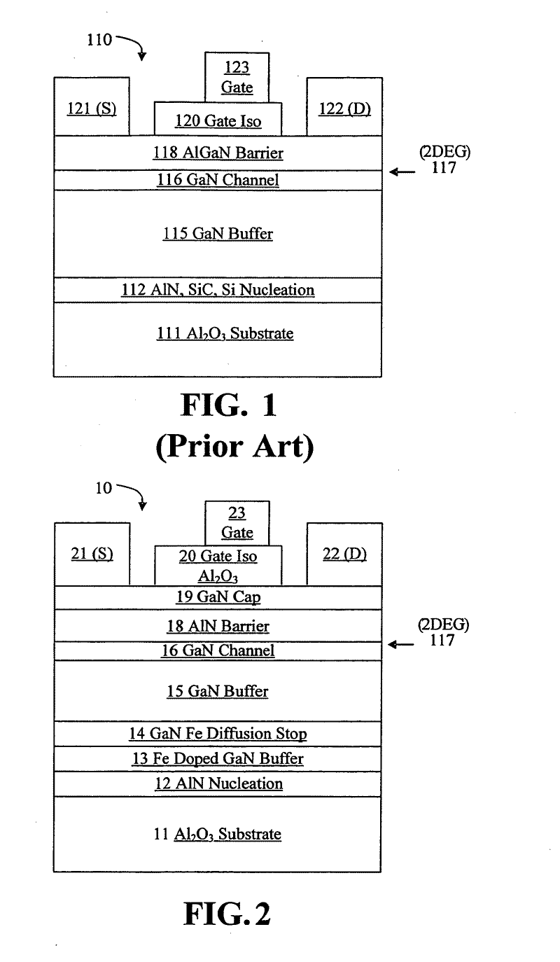

### DETAILED DESCRIPTION

The present invention provides low defect buffer layers for periodic table group III nitrides materials based devices, usually heterojunction devices including including high electron mobility transistors (HEMTs), and integrated methods of fabricating the same. Overview descriptions are provided followed by an overview example and then further followed by various working examples. However, the present invention may be embodied in many other periodic table group III nitrides materials based devices and it should not be construed as limited to the embodiments set forth herein. It should be noted that the sizes of layers or regions are exaggerated for illustrative purposes and, thus, are provided to illustrate the general structures of the present invention.

One HEMT according to the present invention comprises a high resistivity low-defect gallium nitride (GaN) layer with an aluminum nitride (AlN) barrier layer on it forming a heterojunction. The AlN barrier layer has a wider bandgap than the GaN layer and a two dimensional electron gas (2 DEG) is formed at the AlN/GaN interface. Source and drain ohmic contacts are later formed on the HEMT structure to make contact to the 2 DEG through the barrier layer. A non-ohmic gate contact is also deposited on the HEMT structure, between the source and drain contacts, for modulating the conductivity of the 2 DEG in between the source and drain contacts by applying a gate bias. Optionally, a thin insulating layer can be deposited on the HEMT structure before depositing the gate contact, forming a metal oxide semiconductor (MOS) structure, to reduce the potential for excessive gate leakage currents and/or increase the device breakdown voltage.

The invention also includes methods for fabricating HEMTs. In one embodiment, a resistive, low-defect GaN buffer and a GaN channel layer are grown by molecular beam epitaxy (MBE) followed by the growth of a AlN barrier layer with a thickness lower than the critical thickness for the formation of dislocations and/or cracks.

In another embodiment, the MBE growth of AlN/GaN HEMT, as stated above, is followed by deposition of a thin resistive GaN cap layer to modify the 2 DEG density by modifying the total strain in the AlN barrier layer.

In a further embodiment, the MBE growth of the AlN/GaN HEMT as stated above and with or without the GaN cap layer can be followed by in-situ MBE deposition of a thin film (less than 3 atomic layers) of aluminum metal at low temperatures. On exposure to air, the Al metal films form a thin layer of aluminum-oxide (Al₂O₃). Additional oxide films can be deposited if needed for device processing, using conventional techniques such as sputtering or vapor deposition methods, followed by further device processing procedures.

In a preferred embodiment, a HEMT structure is grown by an MBE process on a substrate selected from sapphire, SiC or Si and comprises an AlN nucleation layer about 30 nm thick, a GaN:Fe buffer layer about 0.5 μm thick, an Fe diffusion stop layer about 0.3 μm thick, a GaN buffer layer at least about 0.3 μm, preferably at least about 0.5 μm, more preferably, in the range of 1-2 μm thick, a GaN channel layer about 100 nm thick, an AlN barrier layer in the range of 2-5 nm, more preferably in the range of 2-4 nm, still more preferably about 3.5 nm thick, and optionally either 1) a GaN cap layer in the range of 0-5 nm, preferably in the range of about 1-2 nm, more preferably about 1 nm thick or 2) an Al passivation layer a few monolayers thick or 3) the layer in 1) followed by the layer in 2). The process is carried out as an integrated series of steps in a single system without breaking vacuum.

FIG. 2 shows a schematic layer diagram of an AlN/GaN based HEMT structure, 10, as a device from a fabricated semiconductor device wafer, this device having a GaN buffer layer exhibiting a relatively low density of crystal defects, and with all semiconductor material layers therein having been grown in an ultrahigh vacuum (UHV) molecular beam epitaxy (MBE) system. The method and result of making such structures is disclosed in more detail in the various working examples set out below, but an overview thereof is provided in the following. In this overview embodiment, the fluxes of atomic Al, Ga and any doping impurities for MBE growth are generated using effusion ovens in the molecular beam epitaxy system. The reactive nitrogen flux is produced by an inductively-coupled radio frequency (RF) plasma source. In situ techniques including reflection high energy electron diffraction (RHEED), optical reflectometry and pyrometry are used to monitor the growth quality and to control in the MBE system the growth conditions at the growth surfaces on layers being currently grown including growth surface temperature and periodic table group III element fluxes to group V element fluxes ratios provided to the growth surfaces.

As shown in FIG. 2, HEMT structure 10 comprises a substrate, 11, that can be chosen to be formed alternatively of any of sapphire (Al₂O₃), silicon carbide (SiC), or silicon. On any such substrate, following a vacuum thermal cleaning of the surface thereof upon which layer growth is to occur, an AlN nucleation layer, 12, is grown in the MBE system with an Al to N flux ratio of about 1:1 to ensure growth of a consistent resulting material while avoiding Al droplet formation. On a sapphire substrate, on which the following example, the growth temperature is typically about 750° C. and this nucleation layer is typically grown to be 20 nm to 30 nm thick. The thicknesses given in the example would be less on the other substrates because of the resulting greater thermal mismatches otherwise lead to layer crackings.

Next, a highly resistive GaN multi-stage buffer layer, 13, is grown on the exposed surface of nucleation layer 12 to provide a layer having a smaller density of crystal defects to support a following layer. Point defects in the layer stop some of the threading dislocations present from propagating further, and surface roughness based areal strain differences at the final grown surface redirect some threading dislocations away from this final surface. Layer 13 is grown with a iron (Fe) doping level of about 1E17 cm⁻³ to improve the buffer resistivity by creating deep acceptor levels in GaN to capture electrons made available therein due to the crystal defects still occurring in this layer due to its being grown on layer 12 of another kind of material, i.e. a non-native material predecessor layer. High resistivity is needed to avoid having this layer provide a shunt path for charge carriers in the subsequently provided channel layer. The MBE growth of the GaN buffer layer 13 is started in a Ga-rich condition at the growth surface, by having a Ga to N flux ratio of greater than 1, for typically the first tenth of the layer 13 thickness to promote the growth surface of layer material being smooth. The remaining layer portion is grown in an N-rich condition at the growth surface to enhance incorporation of Fe impurities in GaN and to leave a smooth final grown surface for the next layer to be grown thereon. In this sapphire substrate example, the growth temperature in the MBE system is typically about 725° C. at the growth surface with layer 13 grown to a typical thickness of 0.7 μm.

Next, a diffusion stop layer, 14, of undoped GaN is grown beginning under an N-rich condition at the growth surface for typically the first eight tenths thereof to limit the diffusion of Fe impurities occurring at the final surface of layer 13 to essentially tailing off to a negligible density through the thickness of layer 14 rather than continuing into the layers to be provided following layer 14. These Fe impurities in layer 14 as acceptors here, too, increase the resistivity of the layer. The MBE growth conditions are then made Ga-rich at the growth surface for the remaining growth of layer 14 to provide a finally grown surface that is again smooth for the subsequent layer to be grown thereon. Layer 14 is typically grown in the MBE system at a temperature of about 725° C. at the growth surface to a typical thickness of 0.3 μm. Again, point defects in the layer stop some of the threading dislocations present from propagating further, and surface roughness based areal strain differences at the final grown surface redirect some threading dislocations away from this final surface.

An undoped GaN buffer layer, 15, is then grown on layer 14 at a typical temperature of 725° C. at the growth surface to a substantial thickness exceeding 0.5 μm, typically 1.0 μm, to provide many more point defects in the layer stop many of the threading dislocations present from propagating further, and again with surface roughness based areal strain differences at the final grown surface redirect some threading dislocations away from this final surface. The much reduced density of crystal defects achieve in this layer leaves it with a large resistivity, and the GaN material therein leaves a finally grown surface that is smooth for the GaN channel layer to next be grown thereon. During growth of GaN layers 13, 14, and 15, available in situ measurement tools such as RHEED and/or optical reflection are used to avoid formation of GaN metal phase (droplets) on the surface. Also, some portions or all of the layer materials forming GaN material layers 13, 14, and 15 may further contain a constant or variable Al composition, up to 100%, including AlGaN or AlN layers or multi-layer structures such as superlattices for various purposes including the modification of thin film strains, the reduction of layer cracking, or the further reduction of crystal defects.

The growth of GaN layers 13, 14, and 15 may be interrupted, i.e. the deposition fluxes stopped, to allow making measurements or for other purposes to thereby result in the impurities ever present in the vacuum depositon chamber of the MBE system accumulating on the final grown surface of buffer layer 15 during the interruption following completion of the growth of this layer. These impurities must be covered over and trapped there by the growth of a channel layer, 16, on the final grown surface of buffer layer 15 to form a heterojunction using GaN material that is typically undoped, this growth to be to an adequate thickness for this purpose to prevent those impurities from having an effect on the opposite side of the channel layer. Typically, the GaN material for channel layer 16 is grown at 700° C. at the growth surface to a thickness typically of 100 nm but may range from 20 to 200 nm. The final growth surface of GaN channel layer 16 provides the interface between layer 16 and a barrier layer of a different material, AlN, to be subsequently grown thereon which results in a thin electron sheet charge region, 17, being provided in that channel layer adjacent this interface.

However, GaN channel layer 16 and this barrier layer, 18, of AlN grown on layer 16, are grown in sequence one after the other without an interruption in at least one deposition material flux being used to grow them (though stopping one kind to switch to another kind to provide the two layers of different kinds of materials). This is a basis for reducing the effects of the inevitable accumulating of unwanted chamber impurities on these layers, and so on the quality of sheet charge region 17 resulting at the interface between these two layers, this sheet charge typically being about 10 to 20 nm thick and what is termed a two dimensional electron gas. Channel layer 16, as stated, is preferably undoped, but may be doped with various substances to adjust the electron charge carrier concentration in the sheet charge region or modify the energy bands in that region.

Barrier layer 18 of AlN is grown at typically 700° C. at the growth surface on GaN material channel layer 16 to a thickness less than about 5 nm since thicker barrier layers result in the formation of dislocation defects or layer cracks or both. The electron charge carriers in sheet charge region 17 result from piezoelectric polarization in the channel layer due to the lattice mismatch between GaN material channel layer 16 and AlN material barrier layer 18 and the spontaneous polarization there due to surface charges in barrier layer 18 keeping the sheet charge in channel layer 16 near the interface. The sheet charge is also confined there by the larger band gap energy of AlN material in barrier layer 18 as compared to the band gap energy of the GaN material in channel layer 16. The defect density at the surface of barrier layer 15 formed as above is reduced to being less than 1E10 cm⁻³ to be around the order of 1E9 cm⁻³, or less than 5E9 cm⁻³ or even less than 2E9 cm⁻³, to thereby permit a mobility for electrons in sheet charge region 17 exceeding 1100 cm²/volt-second or even 1800 cm²/volt-second

The charge carrier density in sheet charge region 17 can be selected to be reduced by modifying the strain in AlN barrier layer 18 through growing, at typically 700° C., a thin (1 to 3 nm) cap layer, 19, of undoped GaN on AlN barrier layer 18. GaN cap layer 19 can also help reduce the surface states in AlN barrier layer 18. Thicker versions of GaN cap layer 19 can be grown on AlN layer 18, but without much further effect on sheet charge region 17. Undoped GaN in cap layer 19 may be also replaced by other cap layer semiconductor materials including p-doped GaN, or other doped or undoped material layers such as InGaN or AlGaN with different In and Al composition for further selected alterations of pertinent energy band diagrams, of barrier thicknesses, or of reductions in surface state density or some combinations thereof.

Following the growth of a cap layer 19, if chosen to be provided, layer growth in the MBE system is stopped by closing off the growth materials fluxes and cooling down the wafer down to room temperature. The semiconductor device wafer so formed is then removed from vacuum chamber for thin film characterization and wafer processing. A further alternative, before removing the semiconductor device wafer from the MBE system vacuum chamber, 2 to 3 atomic layers layers of metallic aluminum can be grown by molecular beam epitaxy, at typically 700° C., on the wafer devices last exposed surfaces at room temperature to thereafter form a thin aluminum oxide (Al₂O₃) layer upon exposure to oxygen. This in-situ deposited oxide layer can help passivate the surface states of the AlN material at exposed surfaces of barrier layer 18 or provide a protective layer for the deposition of a thicker oxide layer during the wafer processing or both.

Further wafer processing steps to produce HEMT devices from the semiconductor device wafer include microelectronic lithography procedures to 1) isolate the devices through performing a mesa etch to a depth of a few hundred angstroms below the interface between channel layer 16 and barrier layer 18 by a dry etching technique such as reactive ion etching (RIE) or inductively coupled plasma (ICP) etching, 2) depositing an optional gate isolation layer 20 of a material such as aluminum oxide, silicon nitride, silicon dioxide, or other isolating films and any combinations of the same for providing MOS-HEMTs, 3) deposit a ohmic source contact, 21, and an ohmic drain contact, 22, typically in a sequence of metallic layers and typically of 30 nm of Ti, 200 nm of Al, 300 nm of Ni, and 200 nm of Au, and 4) deposit non-ohmic (Schottky) metal gate contact 23 on optional GaN cap layer 19 or on optional gate isolation layer 20, or both, or directly on the AlN barrier layer 18 in the absence of the optional layers 19 and 20 again typically in a sequence of metallic layers typically of 20 nm of Ni and 300 nm of Au. With a voltage applied between contacts 21 and 22, electrical current flows in sheet charge region 17 that is selectively reducible by introducing a voltage of selected magnitudes on gate contact 23.

Several examples were grown with a structure corresponding to that shown in FIG. 2, described above. All examples were grown in an ultrahigh vacuum (UHV) molecular beam epitaxy (MBE) system with a load-lock, a UHV preparation chamber, and a UHV growth chamber, all connected by gate valves. This system was a Perkin Elmer, Waltham, Mass., model PE-425-B, modified for III-nitride growth. (The PE-425-B is an older MBE system no longer commercially available, but is typical of many that are available.) The MBE system modifications included adding cryo-pumps to handle higher nitrogen gas loads and pressures, and changing the substrate heater to a pyrolytic-boron nitride (PBN) encapsulated graphite heater capable of operation up to ˜1200° C. Other thin-film deposition and monitoring equipment, with model numbers indicted, was supplied by SVT Associates, Inc., Eden Prairie, MN.

Fluxes of atomic aluminum (Al) and gallium (Ga), for thin film growth, and iron (Fe), for impurity doping, were generated by evaporating high-purity elemental materials from

PBN crucibles in separate effusion sources: The Ga effusion source was a “hot-lip” cell, model SVTA-HL-40-450, with a higher temperature near the lip of the PBN crucible to avoid Ga droplet formation. The Al source was a “cold-lip” cell, model SVTA-CL-22-450, with a “cold-lip” with a lower temperature near the lip of the PBN crucible to minimize Al creeping out of the crucible. The other sources, including the iron effusion cell, were standard type cells, model SVTA-SF-22-450.

The reactive nitrogen flux was produced by a model SVTA-RF-4.50 inductively-coupled radio frequency (RF) nitrogen plasma source. The water-cooled nitrogen RF plasma source was equipped with ion deflection grids and deflector plates to minimize thin film damage by high-energy ions. RF power from 300 W to 400 W, provided by a 13 MHz supply through an RF matching box, and nitrogen flow rates from 2 sccm to 5 sccm, controlled by a mass flow controller (MFC), were used at different stages of epitaxial growth, as further explained below. It is believed that other equipment may be used to provide a reactive nitrogen flux for the growth of nitride films, such as gas sources, e.g., ammonia (NH₃) gas injectors, or, electron cyclotron resonance (ECR) plasma sources, but these were not used for these examples.

All the sources in the MBE system were equipped with a pneumatic shutter that could be opened or closed in a fraction of a second for precise control of thin-film thickness. For Al₂O₃ deposition, an atomic layer deposition (ALD) system, model SVTA-ALD-P-100B, was used. It is believed that comparable equipment readily available from other vendors would also be suitable for the working examples described herein.

All starting materials are commercially available. Both elemental Ga and Al were 99.999% pure or better and the elemental Fe was 99.99% pure or better. The nitrogen gas was 99.9999% pure, with the major residual impurity being Argon, however an inline ultrahigh purity gas filter from Areonex, Inc. of San Diego, CA, model SS-36KF-4R was used to further reduce the water and oxygen trace impurities.

Substrates for some examples used a 2-inch diameter c-plane sapphire (Al₂O₃) wafer, commonly available from a number of vendors such as Crystal Systems, Inc., of Salem, Mass., and Kyocera of Kyoto, Japan. Substrates for other examples used a 2-inch diameter semi-insulating 6H-polytype silicon carbide (6H-SiC) from II-VI, Inc., of Saxonburg, Pa., with resistivity of 5E10 Ω·cm or more. Substrates from all these vendors are commonly used for epitaxial growth without further polishing or etching. For improved heating uniformity during growth, all substrates were purchased as “single-side polished” with a rough polish on the backside and “epi-ready” polish on the growth side. For both type of substrates, the pre-growth preparation included standard clean room “degreasing” processes consisting of an acetone batch, then an isopropanol bath, followed by DI water rinse and spin-drying in dry nitrogen atmosphere. The substrates were then loaded into an electron-beam evaporator to deposit ˜1 μm of titanium on the roughly-polished backside of the wafer for improved radiative heat absorption and temperature uniformity during growth. All chemicals used for substrate preparation were high-purity electronics grade.

During MBE growth, parameters such as substrate and source temperatures were computer controlled for convenience and increased consistency using commercially available software, an SVTA RoboMBE package, but this does not have any special requirements and equivalents are commonly available in the industry.

As is common in periodic table group III nitrides materials MBE systems, the growth quality was monitored in situ using reflection high energy electron diffraction (RHEED) to monitor surface morphology, optical reflectometry to measure film thickness, and optical pyrometry to measure substrate temperature. The combination of optical reflectometry and emissivity-corrected pyrometry was done using a SVTA IS-4000 tool, model IS4K-00, that was also interfaced to the RoboMBE program. This tool conveniently allowed a number of in situ measurements including growth rate measurement, surface temperature calibration and real time surface temperature measurements, with the surface temperature calibrated to an error of less than about ±5° C. More accurate calibration with smaller error is possible with this system but was not required for the processes described in this disclosure.

Fluxes of nitrogen and Ga were calibrated using IS-4000 growth rate measurements for GaN growth under nitrogen and Ga limited growth conditions, respectively. The Al fux was measured by growing a number of calibration AlGaN samples with different Al effusion source temperatures and then performing in situ cathodo-luminescence (CL) measurements, using a model CL-0-2.75 from SVTA, to determine the Al mole fraction by measuring the bandgap versus Al source temperature and comparing to published results. The in situ CL measurements had been previously confirmed by other measurements including x-ray diffraction (XRD) and photo-luminescence (PL) measurements. More accurate and real-time measurement of all growth fluxes are possible using an IS6000 real-time atomic absorption tool from SVTA, model IS6K-03, but such accurate flux measurements were not required for the growth of the examples described below.

AlN/GaN HEMT examples of the current invention follow including a) epitaxial growth of device structures on c-plane sapphire substrates and SiC by RF plasma assisted MBE, b) device processing, c) HEMT structure characterization and d) HEMT device characterization.

a) MBE growth of samples starting with sample 1: Step A1—Substrate preparation: For improved efficiency and uniformity of heating the substrates, an approximately 1 μm thick titanium film was deposited on the backside of a c-plane sapphire substrate 11, in FIG. 2 as detailed above. Other metal film thickness values or film patterns can be used for improved heating depending on the heating arrangement. Also, other refractory metals or metal stacks can be used for this purpose. The substrate 11 was then cleaned with isopropanol, rinsed in DI water and spin-dried in a dry nitrogen atmosphere. Next, the substrate 11 was mounted on a molybdenum wafer holder using tantalum wire clips to avoid thermal stress when the sample is heated in the vacuum chamber. The substrate 11 was then transferred to a UHV preparation chamber, in the MBE system described above, and heated up gradually (in about 1 hour) to about 500° C. and then maintained at this temperature for an hour or more to remove surface contaminations including water and hydrocarbons. To further clean the substrate surface, the substrate 11 was transferred to a connected UHV growth chamber and heated at a rate of about 50° C./min to about 850° C. and maintained at this temperature for 15 minutes or more before reducing the temperature to about 780° C. before starting the growth process.

Step A2—AlN nucleation layer 12: The sapphire substrate 11 was exposed to a flux of active nitrogen from the RF plasma source for about 10 minutes at about 780° C. with an RF power of about 450 W and nitrogen flow rate of about 3 sccm. Next, an approximately 30 nm AlN nucleation layer 12 was grown by first opening the Al source shutter for 2 sec; then opening the N source shutter for 10 sec; next opening the Al shutter for 2 more sec and then leaving both Al and N shutters on for 150 sec; and finally, closing the Al shutter and leaving the N shutter open for another 60 sec. The AlN growth was done with an Al to N flux ratio of slightly more than 1:1 and at a growth rate of about 0.6 μm/hr with RF power of about 350 W and a nitrogen flow rate of about 3 sccm. Under these conditions, the RHEED pattern of the surface showed streaky diffraction spots indicating a smooth AlN nucleation layer 12. The Al to N flux ratio of 1:1 was determined previously using calibration runs to get slightly Al-rich conditions as indicated by a gradual brightening of the RHEED pattern after about 10 to 20 sec of exposure to N flux after the growth of the AlN layer.

Step A3—Fe-doped GaN buffer layer 13: The substrate temperature was reduced to about 750° C. and about 0.5 μm of GaN 13 was grown on the AlN layer 12, at a growth rate of about 0.6 μm/hr, while a sufficient Fe flux, as determined by SIMS measurements on previous test samples, was used to produce an estimated Fe doping concentration of about 5E17 cm-3. For this layer, after about 2 minutes of growth under Ga-rich conditions the substrate temperature was reduced to about 730° C. and the Ga flux was adjusted for an effective Ga/N flux ratio of slightly less than 1:1 (i.e., slightly N-rich conditions.) This growth condition, which was chosen to enhance Fe incorporation into the Ga sites of the GaN crystal, resulted in rough surface as indicated by transmission features in the RHEED pattern.

Step A4—Fe diffusion-stopping layer 14: To limit the diffusion of Fe into the subsequent layers, the Fe diffusion-stopping layer 14, was grown under similar N-rich conditions, as in Step 3 above, but with the Fe flux turned off. The undoped GaN diffusion-stopping layer 14 was grown to a thickness of about 0.3 μm.

Step A5—Undoped GaN buffer layer 15: Following the growth of Fe-stopping layer 14, the Ga flux was increased to reach a slightly Ga-rich condition with the effective Ga/N flux ratio believed to be about 1.05:1. This resulted in smoothing of the surface as indicated by sharp streaks in the RHEED pattern. The thickness of undoped GaN buffer 15 was about 2 μm and it was grown at a rate of about 0.6 μm/hr and temperature of about 730° C. Both substantially thicker and thinner undoped GaN buffer layers grown at higher and lower growth rates were used in other examples of the current invention, but a thickness of 1-2 μm for the undoped GaN buffer 15 was found to produce the best results. During the growth of buffer layer 15, growth was interrupted about every 30 to 60 minutes by closing both Ga and N shutters for few minutes to evaporate the accumulating excess Ga from the surface in order to avoid the formation of liquid Ga droplets. The SVT-IS4000 was used to monitor the Ga evaporation from the surface by measuring the change in the surface reflection. Brightening of the RHEED pattern also was used to confirm the complete desorption of the extra Ga from the surface.

Step A6—Active layer growth: The growth of the AlN/GaN HEMT active device layer started with the growth of a GaN channel layer 16 with a thickness of about 100 nm under a slightly Ga-rich condition at 730° C. To minimize impurities at the AlN/GaN interface, the growth of AlN barrier layer 18 was started without interruption right after the growth of GaN channel layer 16 by closing the Ga shutter and opening the Al shutter. In spite of the presence of extra Ga at the surface, due to much higher binding energy of AlN compared to GaN, mainly AlN is formed under these conditions. Based on the growth rate measurements of 0.6 μm/hr done during the Ga-rich growth of the undoped GaN buffer 15, the Al shutter was closed just after growing 2 nm of AlN barrier 18. Depending on the thickness of the AlN layer 18, both the carrier concentration and mobility of the two dimensional electron gas (2 DEG) 17, formed at the interface of GaN channel 16 and the AlN barrier 18, could be adjusted as further described below. However, it was found that an AlN layer 18 thickness of about 3.5 nm can result in the lowest sheet resistivity, which is proportional to the product of the 2 DEG carrier concentration and mobility.

Step A7—GaN cap layer 19: Lastly, a 1 nm GaN cap layer 19 was grown for improved ohmic contact formation and reduced surface states. In other examples, the thickness of the GaN cap layer 19 was varied from 0 to 10 nm. It was found to affect the density of the 2 DEG 17, with thicker GaN resulting in lower 2 DEG density. This effect saturated at a GaN cap layer 19 thickness of about 5 nm.

The active device layer of the invention is the combination of channel layer 16 and barrier layer 18 and the optional GaN cap layer 19. Of great importance to high-quality growth of this active layer is the low level of defects in the GaN buffer layer 13 with the combination of layers 13, 14 and 15, under the growth conditions described above. In addition, the quality of both the active device layer and the low-defect GaN buffer layer 13 can be affected by the quality (e.g., smoothness and stoichiometry) of the AlN nucleation layer 12.

Samples 2-5: To determine the effects of the AlN barrier layer 18 thickness, samples 2, 3, 4, & 5 were produced using essentially the same process steps as above except that the thickness was increased from 2.0 to 3.0, 3.5, 4.0, & 5.0 nm, respectively.

Sample 6: To determine the effects of the GaN cap layer 19 thickness, sample 6 was produced using essentially the same process steps as for sample 2 above (3.0 nm barrier layer 18) except that the thickness was increased from 1.0 to 2.0 nm.

Sample 7: To determine the effects of substrates, sample 7 was produced using essentially the same process steps as above for sample 2, except that a 6H-SiC substrate was used and the thickness of GaN stop layer 14 was decreased from 2.0 to 1.0 μm. For this sample also, the SiC substrate was not nitrided, but heated to about 1000° C. to remove oxide layers from the surface before reducing to 700° C. for growth. A very sharp RHEED pattern was observed.

Sample 8: To use as a reference, this sample was produced using essentially the same process steps as for sample 1, except that in Step A6, after growth of the GaN channel layer 16, instead of the AlN barrier 18, a flux of both Ga and Al was introduced to produce a 20 nm thick Al0.25Ga0.75N barrier layer 18.

Sample 9: This was produced using essentially the same steps as for sample 7, except that in Step A6, after growth of the GaN channel layer 16, instead of the AlN barrier 18, a flux of both Ga and Al was introduced to produce a 20 nm thick A10.25Ga0.75N barrier layer 18 (as in example 7).

b) HEMT device processing: Step B1—wafer preparation: The AlN/GaN HEMT wafers produced by Steps A1-A7 above, were prepared for device processing by etching off the backside titanium metal and any remaining extra Ga on the surface in a solution of HCL:H2O (3:1) with a few drops of HF added.

Step B2—ALD gate oxide deposition: To form a metal-oxide-semiconductor (MOS) HEMT structure, a 30 nm Al2O3 layer 20 was grown on the wafer by atomic layer deposition (ALD.) (A thinner 15 nm layer thickness was used on other samples not listed above with similar results.) Deposition of the gate oxide by low damage ALD process is an important step for AlN/GaN HEMTs to prevent damage to the thin barrier layer that could happen with other oxide deposition techniques such as plasma-enhanced chemical vapor deposition (PECVD), sputtering, or electron-beam evaporation. The ALD deposition of the Al2O3 oxide layer 20 (illustrated in FIG. 2 after Step B3, below) used a high purity metal-organic chemical precursor, tri-methyl-aluminum (TMA), as the aluminum source, and high purity water vapor for oxygen. The process to form each monolayer of Al2O3 included pulsed flooding the ALD chamber with TMA for 1 sec, removing the residual precursor with nitrogen gas flushing and vacuum pumping for 70 sec, pulsed flooding with H2O for 70 sec, and removing the residual water and any gas-phase reactants by a second nitrogen flush and vacuum pumping for 130 sec. The thickness of the gate oxide layer 20 was determined based on thicker Al2O3 films grown separately and calibrated by standard thin-film measurements.

Step B3—Device mesa etch: Standard photolithography was used to pattern photoresist (PR) on the Al₂O₃-covered AlN/GaN wafer prepared in Step B2. This was followed by mesa isolation, to a depth of about 50 nm, (which may also produce etching under the PR covered area) by inductively coupled plasma (ICP) etching using a chlorine-based gas mixture. A second PR photolithography was used to selectively etch the Al₂O₃ oxide layer using a standard buffered oxide etch in order to expose the GaN layer in the source 21 and drain 22 contact regions.

Step B4—Metal contact formation: Standard photolithography was used for patterning PR in order to form both ohmic metal contacts (source 21 and drain 22) and gate metal contact 23, by electron beam deposition followed by ultrasonic-assisted liftoff in an acetone bath. The ohmic metal stack from bottom to top consisted of 20 nm titanium (Ti)/150 nm aluminum (Al)/30 nm nickel (Ni)/100 nm gold (Au). To improve ohmic contact of the source 21 and drain 22 regions to the 2 DEG 17 through the cap 18 and barrier layer 19, the wafer was annealed at 800° C. in a nitrogen atmosphere for 30 sec in a rapid thermal annealing (RTA) chamber before the deposition of the gate metal 23. We believed that the buffered oxide etch also creates small holes in the barrier layer in the source 21 and drain 22 regions, facilitating the formation of more conductive ohmic contacts. The gate metal 23, deposited on the oxide layer 20, consisted, from bottom to top, of 20 nm Ti/100 nm Au. It is believed that these steps are common and well know in the art. Other metal stacks have been also used for both source/drain and gate contacts in other examples of the current invention with slightly different results.

The completed MOS-HEMT device 10, as shown in FIG. 2, had a source 21 to drain 22 separation of 4.5 μm (not drawn to scale) and the gate 20 length between source and drain was 1.2 μm and width (into the plane of the figure) was 200 μm.

c) HEMT structure characteristics: Table 1 is a listing of the samples grown as described above.

TABLE 1

| | | | | HEMT Structure | |
|---|---|---|---|---|---|
| | | μ_{RT} | | Cap (19)/Barrier (18)/Channel | |
| Sample # | nₛ (cm⁻²) | (cm²/V · s) | ρₛ (Ω/□) | (19) | Substrate |
| 1 | 5.47E+12 | 1220 | 937 | 1 nm GaN/2.0 nm AlN/3.0 μm GaN | Al₂O₃ |
| 2 | 1.83E+13 | 1610 | 213 | 1 nm GaN/3.0 nm AlN/3.0 μm GaN | Al₂O₃ |
| 3 | 2.50E+13 | 1780 | 140 | 1 nm GaN/3.5 nm AlN/3.0 μm GaN | Al₂O₃ |
| 4 | 3.27E+13 | 1130 | 170 | 1 nm GaN/4.0 nm AlN/3.0 μm GaN | Al₂O₃ |
| 5 | 4.10E+13 | 110 | 1390 | 1 nm GaN/5.0 nm AlN/3.0 μm GaN | Al₂O₃ |
| 6 | 1.68E+13 | 1630 | 228 | 2 nm GaN/3 nm AlN/3.0 μm GaN | Al₂O₃ |
| 7 | 2.30E+13 | 1460 | 185 | 1 nm GaN/3.5 nm AlN/2.0 μm GaN | 6H—SiC |
| 8 | 1.05E+13 | 1830 | 325 | 2 nm GaN/Al_{0.2}Ga_{0.8}N/3.0 μm GaN | Al₂O₃ |
| 9 | 9.60E+12 | 1990 | 327 | 2 nm GaN/Al_{0.2}Ga_{0.8}N/2.0 μm GaN | 6H—SiC |

After growth, but before removal from the MBE system, the substrate temperature was lowered to room temperature (RT) and wafers removed to a connected UHV analysis chamber for in situ cathodo-luminescence (CL) measurements to examine the optical quality of the grown layers. For all the samples, a typical CL peak at 365 nm with a FWHM of about 6 nm for GaN indicated high quality growth.

After removal from the UHV analysis chamber, room temperature (RT) van der Pauw Hall measurements were performed to determine 2 DEG mobility, μ_{RT}(in units of cm²/V·s), and sheet carrier density, ηₛ (in units of cm⁻²), from which the sheet resistivity, ρₛ (in units of Ω/□), can be calculated as ρₛ=1/(e.nₛ. μ_{RT}), where e is the electron charge ˜1.602E-19 coulombs. For samples 1-5, the 2 DEG density, nₛ, increases with increasing barrier 18 thickness, whereas the Hall mobility, μ_{RT}, decreases. For sample 3, the optimum AlN thickness of 3.5 nm produced the lowest as-grown RT ρₛ of ˜140 Ω/□. This is about twice the channel conductivity of typical high-quality AlGaN/GaN HEMTs grown for reference sample 8 (on sapphire substrate) or sample 9 (on SiC substrate). Sample 6, shows that ρₛ with a thicker GaN cap layer 19 is slightly worse as is the equivalent sample 7, grown on 6H—SiC. Note that these are typical values and there are some variations in measured pₛ values across the wafer.

The highest RT and 77 K electron mobility values measured a AlN/GaN HEMT sample (not listed in table 1) similar to sample 2, but without a cap layer 19. These were 1850 cm²/V·s and 6530 cm²/V·s, respectively, at a relatively constant nₛ value of ˜1.6E13 cm⁻². This nₛ value is enough lower than sample 2 so that the resistivity of 214 Ω/□ was 50% higher.

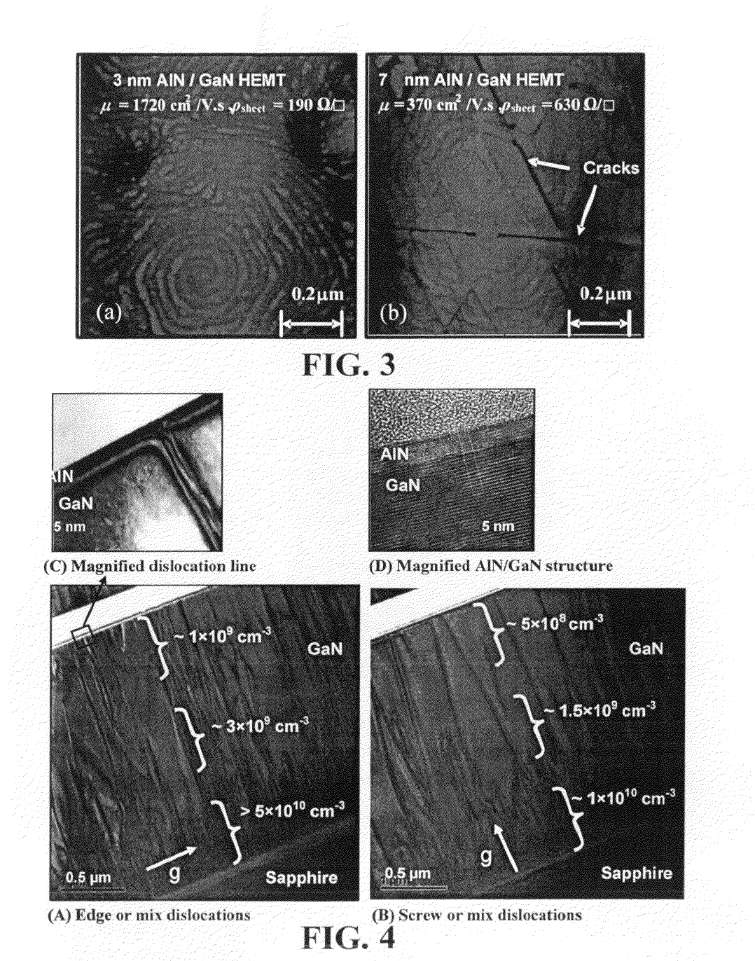

Other examples (not listed in Table 1) were grown with thicker or thinner AlN barrier layers 18 and GaN cap layer 19 to change the sheet carrier density of the 2 DEG by varying the polarization fields. FIG. 3 is an atomic force microscopy (AFM) image of an AlN/GaN surface with two different thicknesses showing (a) atomic steps for an AlN thickness of 3 nm, and (b) crack lines superimposed on surface steps for an AlN thickness of 7 nm, that is, (a) a sample similar to sample 2 with an AlN barrier 18 thickness of 3 nm and (b) another sample with a barrier thickness of 7 nm. The sample in (b) shows cracking of the AlN layer due to mismatch in both lattice parameter and thermal expansion with the underlying structure resulting in a large reduction in electron mobility and, hence increase in sheet resisitivity of the 2 DEG 17 (μ_{RT}=370, ρₛ=630) than the sample in (a) (μ_{RT}=1720, ρₛ=190). Other samples (not shown) with AlN barriers layers 18 of less than 2 nm had high values of sheet resistance, probably, due to inadequate confinement of the 2 DEG in the quantum well at the AlN/GaN interface.

The growth of high quality AlN/GaN HEMTs by an all MBE process demonstrated here is partly related to the growth of high quality GaN buffer layers in the current invention. FIG. 4 shows cross-sectional transmission electron microscopy (TEM) images of an AlN/GaN HEMT with an integrated, low-defect, semi-insulating GaN buffer layer, grown by MBE on c-plane sapphire having an epitaxial structure corresponding to layers 11 through 19 in FIG. 2; that is, grown by MBE on sapphire (0001) for diffraction vector normal and parallel to the c-axis showing (A) edge or mixed threading dislocations, (B) screw or mixed threading dislocations, (C) zoomed images of a dislocated region, and (D) a dislocation free region. (The 1 nm GaN cap layer 19 is hard to distinguish because of low contrast and some surface oxidation.) The TEM images labeled A & B are obtained under two different electron diffraction conditions to show the density of edge/mixed and screw/mixed threading dislocation (TDs), respectively. (TEM images C & D show magnified sections of the images A & B, respectively.) The effectiveness of the current invention in reducing the density of TDs in GaN layers grown by MBE on sapphire is demonstrated in TEM images A & B where a very high starting TD density in the GaN buffer layer 15 is reduced by more than an order of magnitude, to about 1E9 cm⁻², within less than 2 μm of GaN buffer growth. (The samples listed in Table 1 all had a TD<3E9 cm⁻² with some localized regions <1E8 cm⁻².) Growing low-defect GaN thin films without growing very thick buffer layers is important for commercial production on large diameter substrates and on substrates with very different lattice parameters and coefficients of thermal expansion such as silicon.

The importance of low TD GaN for the growth of AlN/GaN HEMT structures is shown in TEM images C & D, in FIG. 4. Image C shows a TD creating a defective region in the GaN channel 16 and AlN barrier 18 layers surrounding the 2 DEG 17. Lower values of electron mobility are expected for 2 DEG in this defective region due to different defect and roughness scattering effects. A high density of such defective regions and/or thin film cracks is believed to explain low values of 2 DEG mobility in the prior art. In contrast, TEM image D shows a dislocation free region of GaN channel 16 and AlN barrier 18 layers with highly ordered atomic layers and an atomically sharp interface between the two. Due to a much lower roughness and alloy scattering in this region, a high electron mobility is expected. As indicated by images A & B, with a low enough density of TDs (˜1E9 cm⁻² or lower), one can obtain an active layer with relatively large connected regions of high mobility 2 DEG to obtain an overall low channel resistivity in these structures. This demonstrates the importance of the present invention for the production of high-quality AlN/GaN HEMTs as well as other III-nitride structures that are significantly affected by the presence of high density of TDs in the active device layer.

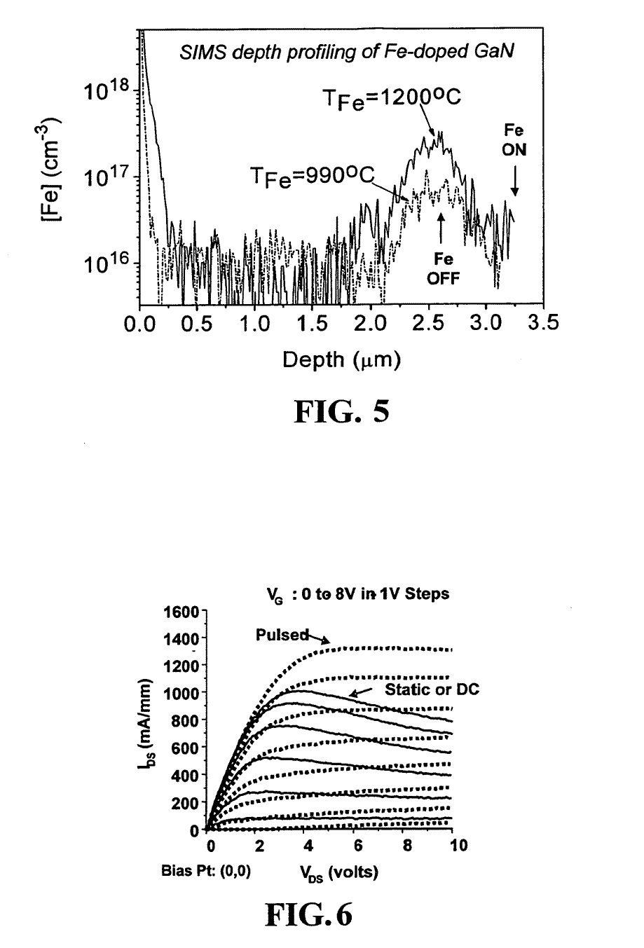

It was found that with a thickness of 0.3 μm or more, the GaN diffusion stop layer 14 is very effective in limiting Fe diffusion into the subsequent layers as shown in the secondary ion mass spectroscopy (SIMS) data from the Fe-doped GaN buffer. FIG. 5 shows secondary ion mass spectroscopy (SIMS) depth profiling of Fe-doped GaN buffer layers with two different Fe source temperatures giving the Fe concentration as a function of depth into the wafer for a typical sample, and showing that under growth conditions used here the Fe impurities are well confined in the GaN layer within about 0.3 μm of growth after closing the Fe source flux. (The spike in the SIMS Fe signal at the surface is believed to be an artifact of these measurements.) This shows that there is some Fe diffusion toward the wafer surface after the point in the process where the Fe shutter is turned off, but it is confined to about 0.3 μm under growth conditions used here. In contrast, it is believed that Fe-doped GaN layers grown by MOCVD suffer from a long Fe diffusion tail after the Fe flux is closed in comparison with the Fe-doped GaN grown in the current invention. This may be due to higher growth temperatures used in MOCVD.

d) HEMT device characteristics: Both direct current (DC) and pulsed current-voltage (I-V) characteristics of Sample 5, fabricated in accordance with Steps A1-A7 and B1-B4 above, were measured using an Accent Diva-D225 dynamic I-V analyzer.

FIG. 6 shows the DC (solid line) and pulsed (dotted line) source-drain current versus voltage (or I-V) characteristics as a function of selected gate voltages for an ALN/GaN structure with an oxide-isolated gate forming a metal-oxide-semiconductor (MOS) HEMT device with a gate length of 1.2 μm and a source-drain separation of 4.5 μm. To obtain the family of I-V curves shown in FIG. 6, the gate bias, V_{GS}, was changed from 0 to −7 V in 1 volt steps. The drain to source current, I_{DS}, is plotted in terms of mA/mm of gate width. For the pulsed measurements, the pulse length used was 1 μs and the separation between pulses was 2 ms. The initial bias point for each pulse was V_{GS}=0 and V_{DS}=0.

The figure indicates a peak transconductance, gₘ, of about 250 mS/mm near Vgs=−3 v and Ids=700 ma/mm. One can see the effect of self-heating, which is seen as a drop in DC source-drain current, I_{DS}, at higher source-drain voltages, V_{DS}. This drop in I_{DS} is mainly due to reduction of the 2 DEG mobility at high temperatures, which are usually seen in HEMT devices resulting from the heat generated for operation at higher powers (i.e., higher I_{DS} times V_{DS}).

Other working MOS-HEMT examples fabricated on SiC substrates in the current invention showed much lower self-heating effect due to much higher thermal conductivity of the SiC compared to sapphire allowing more efficient removal of the generated heat from the 2 DEG area.

To lower contact resistance, some samples were thermally annealed in nitrogen at 800° C., but limited to 30 sec. Using transmission line method (TLM) pads, measured contact resistivity as low as ρ_{c}˜5×10⁻⁶ Ω·cm² was obtained.

As used herein, the term “large area” in reference to the GaN material means that such material has a diameter of at least 25 millimeters, or in the case of square or rectangular wafers, a diagonal dimension of at least 25 mm. As used herein, the term “semi-insulating” in reference to the semi-insulating GaN material of the invention means that such material has a bulk resistivity >100 Ω·cm at room temperature (˜25° C.).

In one embodiment, the GaN buffer layers of the invention may have a resistivity >100 kΩ·cm at 200° C. More preferably, the semi-insulating GaN material has a resistivity >1000 kΩ·cm at 300° C. Such values of resistivity may be determined by TLM measurements.

The deep acceptor species can be of any suitable type that is an effective compensator to produce a GaN material that is semi-insulating in character. The deep acceptor species can include one deep acceptor species or more than one such species. In accordance with a preferred aspect of the invention, the deep acceptor species comprises one or more transition metals.

The transition metals useful in the invention can be of any suitable type or types, e.g., scandium, titanium, vanadium, chromium, manganese, iron, cobalt, nickel, copper, zinc, yttrium, zirconium, niobium, molybdenum, technetium, ruthenium, rhodium, palladium, silver, cadmium, hafnium, tantalum, tungsten, rhenium, osmium, iridium, platinum, gold, and mercury

The deep acceptor dopants employed in the practice of the invention accept electrons having an energy level intermediate the valence band and the conduction band of the GaN, e.g., as generated by unintentionally doped impurities or native defects in the material, thereby making the gallium nitride semiconductor into a semi-insulating material. Transition metals can be incorporated into the GaN crystal by using one or more corresponding metal source reagents in the gallium nitride growth process. By way of specific example, Fe doping may be effective with concentrations of from about 1E16 cm⁻³ to about 1E18 cm⁻³, as determined by SIMS or other techniques known to those skilled in the art, in combination with donor concentration less than 1E16 cm⁻³, to yield semi-insulating GaN having a suitable resistivity value, e.g., >100 kΩ·cm.

Although the present invention has been described with reference to preferred embodiments, workers skilled in the art will recognize that changes may be made in form and detail without departing from the spirit and scope of the invention.

1. A method for providing a periodic table group III nitrides materials based heterojunction device, the method comprising:
growing on a substrate a buffer structure having a plurality of buffer structure layers, including plural layers of different kinds of semiconductor materials, all grown by molecular beam epitaxy with an outer layer being of GaN,
growing a channel layer of GaN on the outer layer by molecular beam epitaxy, and
growing a barrier layer of AlN on the channel layer by molecular beam epitaxy to form a heterojunction resulting in an electron sheet charge region being formed adjacent thereto, the buffer structure having a crystal defects concentration sufficiently small to allow electron mobilities in the sheet charge region to exceed 1100 cm²/volt-second.

2. The method of claim 1 wherein the channel layer of GaN grown by molecular beam epitaxy is grown using plural fluxes of materials and wherein the barrier layer of AlN grown by molecular beam epitaxy is grown using plural fluxes of materials such that there is at least one flux of material present throughout the ending of the growth of the channel layer by molecular beam epitaxy and the beginning of the growth of the barrier layer by molecular beam epitaxy.

3. The method of claim 1 wherein the buffer structure has a nucleation layer of AN grown on the substrate by molecular beam epitaxy, a doped buffer layer of GaN grown on the nucleation layer by molecular beam epitaxy incorporating an therein an acceptor type dopant, an acceptor type dopant diffusion stop layer of GaN grown on the nucleation layer by molecular beam epitaxy, and the outer layer grown on the acceptor type dopant diffusion stop layer by molecular beam epitaxy to a thickness exceeding 0.5 μm.

4. The method of claim 1 wherein the buffer structure has a nucleation layer of AlN grown on the substrate by molecular beam epitaxy, a doped buffer layer of GaN grown on the nucleation layer by molecular beam epitaxy incorporating therein an acceptor type dopant, an acceptor type dopant diffusion stop layer of GaN grown on the nucleation layer by molecular beam epitaxy, and the outer layer grown on the acceptor type dopant diffusion stop layer by molecular beam epitaxy to a thickness sufficient to reduce the crystal defects concentration at the outer surface thereof to being less than 5E9 cm⁻³.

5. The method of claim 4 wherein the nucleation layer is grown in the MBE system with an Al to N flux ratio of about 1:1.

6. The method of claim 4 wherein the doped buffer layer is grown in the MBE system initially Ga-rich through a thickness less than half of its final thickness by having a Ga to N flux ratio of greater than 1, and grown N-rich through the remaining thickness thereof while incorporating in the doped buffer layer an acceptor type dopant.

7. The method of claim 4 wherein the acceptor type dopant diffusion stop layer is grown in the MBE system initially N-rich through a thickness more than half of its final thickness, and grown Ga-rich through the remaining thickness thereof.

8. The method of claim 4 further comprising growing a cap layer of undoped GaN on the barrier layer by molecular beam epitaxy.

9. The method of claim 8 further comprising growing an electrical insulating layer on the cap layer by molecular beam epitaxy.

10. A periodic table group III nitrides materials based heterojunction device, the device comprising:
a substrate,
a buffer structure having a plurality of buffer structure layers, including plural layers of different kinds of semiconductor materials, all grown by molecular beam epitaxy with an outer layer being of GaN,
a channel layer of GaN grown on the outer layer by molecular beam epitaxy, and
a barrier layer of AlN grown on the channel layer by molecular beam epitaxy to form a heterojunction resulting in an electron sheet charge region being formed adjacent thereto, the buffer structure having a crystal defects concentration sufficiently small to allow electron mobilities in the sheet charge region to exceed 1100 cm²/volt-second.

11. The device of claim 10 wherein the buffer structure sheet resistivity exceeds 200 Ω/□.

12. The device of claim 10 wherein the electron mobilities in the sheet charge region to exceed 1800 cm²/volt-second.

13. The device of claim 10 wherein the outer layer has a defect concentration less than 5E9 cm⁻³.

14. The device of claim 10 further comprising a cap layer of undoped GaN provided by molecular beam epitaxy on the barrier layer.

15. The device of claim 14 further comprising an electrical insulating layer layer provided by molecular beam epitaxy on the cap layer.

16. The device of claim 10 further comprising the heterojunction device being a high electron mobility transistor having a pair of ohmic contacts separated from the electron sheet charge region by the barrier layer but conductively connected to that electron sheet charge region with the ohmic contacts having a gate structure including a Schottky metal gate contact positioned between them that is separated from the electron sheet charge region by the barrier layer and electrically insulated from that electron sheet charge region.
